(19) United States
(12) Patent Application Publication
(10) Pub. No.: US 2025/0242459 A1
(43) Pub. Date: Jul. 31, 2025

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Yutaka MOMIYAMA, Fukuoka (JP); Ikuo ITAKURA, Fukuoka (JP); Hitoshi SASAKI, Fukuoka (JP)

(21) Appl. No.: 19/035,498

(22) Filed: Jan. 23, 2025

(30) Foreign Application Priority Data
Jan. 25, 2024 (JP) 2024-009231

(51) Int. Cl. B23Q 3/15; B23Q 11/10; H02N 13/00

(52) U.S. Cl. CPC B23Q 3/15; B23Q 11/10; H02N 13/00

(57) ABSTRACT

An electrostatic chuck includes a dielectric substrate 100, and a base plate joined to the dielectric substrate. The dielectric substrate is provided with a flange section that is a part protruding outward along the entire periphery of a part of a side surface of the dielectric substrate on the base plate side. The base plate includes a surface which is closest to the dielectric substrate side and a part of which is joined to the dielectric substrate. A part of the surface, which is not joined to the dielectric substrate, surrounds the flange section along the entire periphery in top view.

### CROSS-REFERENCE TO RELATED APPLICATION

This application is based upon and claims the benefit of priority from Japanese Patent Application No. 2024-009231 filed on Jan. 25, 2024, the entire contents of which are incorporated herein by reference.

### FIELD

The present invention relates to an electrostatic chuck.

### BACKGROUND

For example, in a semiconductor manufacturing apparatus including an etching apparatus, an electrostatic chuck is provided as an apparatus configured to attract and hold a wafer such as a silicon wafer to be processed. The electrostatic chuck includes a dielectric substrate to which an attraction electrode is provided and a base plate which supports the dielectric substrate, and has a configuration in which these are joined to each other. When a voltage is applied to the attraction electrode, an electrostatic force is generated, and the wafer placed on the dielectric substrate is attracted and held.

An outer shape of the dielectric substrate in top view is often identical to an outer shape of a placement surface on which the substrate is placed. In other words, the dielectric substrate often has a thin cylindrical shape. However, with such a configuration, a side surface of a joining layer which joins the dielectric substrate and the base plate is exposed immediately below an outer circumferential end of the placement surface. It is not preferable to expose the joining layer made of, for example, a cured silicone adhesive near the substrate on the placement surface.

Thus, as described in WO 2022/255118, for example, a configuration in which the dielectric substrate is provided with a flange section is employed in some cases. The flange section is a part protruding outward along the entire periphery of a part of a side surface of the dielectric substrate on the base plate side. In the configuration described in WO 2022/255118 described above, the flange section extends up to a position for entirely covering an upper surface of the base plate.

In a case where the dielectric substrate is provided with the flange section, the side surface of the joining layer is exposed at a position on a further outer circumferential side relative to the outer circumferential end of the placement surface. Thus, an exposed part of the joining layer can be distanced from the substrate as compared to a case where the dielectric substrate is not provided with the flange section.

### SUMMARY

Recently, requirements such as cooling performance and the like demanded of electrostatic chucks have significantly increased along with miniaturization and performance enhancement of semiconductor devices. Along with this, dielectric substrates have become thinner as compared to conventional ones, with some having a thickness of less than 4 mm.

When a dielectric substrate is provided with a flange section, the flange section needs to be even thinner with a thickness of 1.5 mm or less, for example. As thinning of dielectric substrates is expected to continue in the future, it may potentially become difficult to ensure sufficient strength of the flange section depending on its shape.

The present invention has been made in view of the above-mentioned issue and is aimed to provide an electrostatic chuck which has a configuration with a flange section provided on a dielectric substrate and can ensure the strength of the flange section.

To address the above-described issue, an electrostatic chuck according to the present invention includes a dielectric substrate including a placement surface on which an object to be attracted is placed, and a base plate joined to the dielectric substrate. The dielectric substrate is provided with a flange section that is a part protruding outward along the entire periphery of a part of a side surface of the dielectric substrate on the base plate side. The base plate includes a flat surface which is closest to the dielectric substrate side and a part of which is joined to the dielectric substrate. A part of the flat surface, which is not joined to the dielectric substrate, surrounds the flange section along the entire periphery when viewed from a direction perpendicular to the placement surface.

In the electrostatic chuck with such a configuration, the flange section of the dielectric substrate does not extend to a position for entirely covering the flat surface of the base plate. Specifically, the protrusion amount of the flange section toward the outer circumferential side is restrained to an extent that the flat surface is exposed to surround the periphery of the flange section. With such a configuration, it may be possible to ensure the strength of the flange section as compared to a configuration in which the flange section protrudes to a position for entirely covering the flat surface.

According to the present invention, it may be possible to provide an electrostatic chuck which has a configuration with a flange section provided on a dielectric substrate and can ensure the strength of the flange section.

### BRIEF DESCRIPTION OF THE DRAWINGS

FIG. 1 is a cross sectional view schematically illustrating a configuration of an electrostatic chuck according to the present embodiment;

FIG. 2 is a cross sectional view illustrating a configuration of a flange section and its vicinity part in detail;

FIG. 3 is a cross sectional view illustrating a configuration of the flange section and its vicinity part in detail;

FIG. 4 schematically illustrates a configuration of a coolant flow path formed in a base plate; and

FIG. 5 is a cross sectional view illustrating a configuration of the flange section and its vicinity part of an electrostatic chuck according to a modification in detail.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

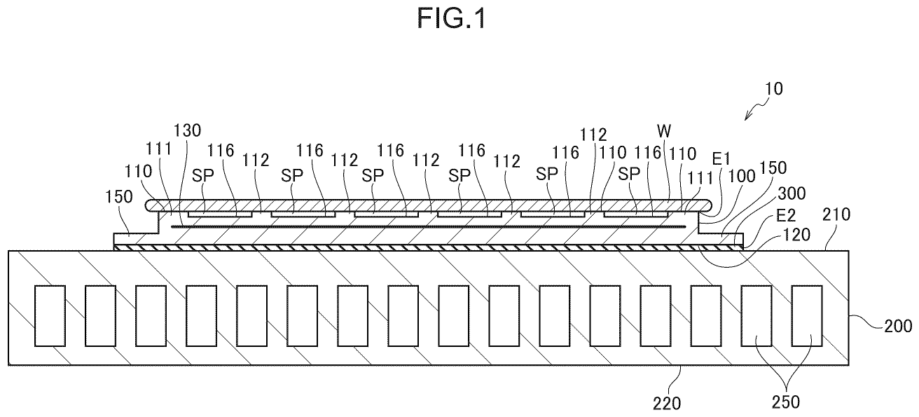

FIG. 1 is a cross sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via a joining layer 300. A perspective in a case where the electrostatic chuck 10 is viewed from the surface 110 side along a direction perpendicular to the surface 110 will also be hereinafter expressed as “top view”. A diameter of the surface 110 is, for example, 290 to 300 mm. An overall thickness of the dielectric substrate 100 is, for example, 1 to 5 mm.

An attraction electrode 130 is embedded inside the dielectric substrate 100. The attraction electrode 130 is a thin planar layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line which is not illustrated in the drawing, an electrostatic force is generated between the surface 110 and the wafer W, and according to this, the wafer W is attracted and held. As a configuration of the above-described feed line, various configurations in related art can be adopted. The single attraction electrode 130 may be provided as so-called a “monopolar” electrode as in the present embodiment, but may also include two attraction electrodes as so-called “bipolar” electrodes.

A depth of a position where the attraction electrode 130 is disposed, in other words, a distance from a bottom surface 116 to be described later to the attraction electrode 130 is, for example, 0.1 to 0.5 mm. A distance from an outer circumferential edge of the attraction electrode 130 to an outside surface of the dielectric substrate 100 (outside surface of a part except for a flange section 150) is, for example, 0.1 to 3 mm.

In addition to the above-described attraction electrode 130, an RF electrode may be embedded inside the dielectric substrate 100. The RF electrode is provided as one of a pair of counter electrodes for generating plasma in the semiconductor manufacturing apparatus. The other of the counter electrodes is provided at a position on the upper side of the electrostatic chuck 10 in the semiconductor manufacturing apparatus. When a high-frequency alternating-current voltage is applied between the counter electrodes, plasma is generated on the upper side of the wafer W and used for processing such as deposition and etching on the wafer W. The RF electrode may be embedded at a position where a distance from the surface 120 is, for example, 0.1 to 4.5 mm. A distance from the attraction electrode 130 to the RF electrode may be, for example, 0.2 to 2 mm. A distance from an outer circumferential edge of the RF electrode to the outside surface of the dielectric substrate 100 may be, for example, approximately 0.1 to 5 mm.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a gas hole which is not illustrated in the drawing. When the helium gas is present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. An upper end of the seal ring 111 becomes a part of the surface 110 and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniform.

A part denoted by a reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. An upper end of each of the dots 112 becomes a part of the surface 110 and abuts against the wafer W. By providing the plurality of thus configured dots 112, warping of the wafer W is reduced.

The dielectric substrate 100 is provided with a flange section 150. The flange section 150 is a part with a shape protruding outward along the entire periphery of a part of a side surface of the dielectric substrate 100 on the base plate 200 side. Thus, an overall shape of the dielectric substrate 100 is not a simple (thin) cylindrical shape. Since the flange section 150 is provided, the surface 120 serving as the surface to be joined is larger than the surface 110 serving as the placement surface. A center of the surface 110 and a center of the surface 120 match with each other in top view. An outer shape of the surface 120 in top view matches an outer shape of the flange section 150 in top view. A thickness of the flange section 150 is, for example, 0.5 to 4 mm.

The base plate 200 is a substantially disk-shaped member which supports the dielectric substrate 100. The base plate 200 is made of, for example, a metallic material such as aluminum. The base plate 200 is joined to the surface 120 of the dielectric substrate 100 via the joining layer 300. A part of a surface 210 on the upper side in FIG. 1 in the base plate 200 serves as a “surface to be joined” which is joined to the dielectric substrate 100 via the joining layer 300. An entire thickness of the base plate 200 is, for example, 30 to 40 mm.

The joining layer 300 is a layer provided between the dielectric substrate 100 and the base plate 200 to join those components. The joining layer 300 is obtained by causing an adhesive made of an insulating material to be cured. According to the present embodiment, a silicone adhesive may be used as the above-described adhesive. It is noted however that the joining layer 300 may be obtained by causing an adhesive made of other types to be cured. In any case, in order that a thermal resistance between the dielectric substrate 100 and the base plate 200 is reduced, a material with a highest possible thermal conductivity may be used as the material of the joining layer 300.

The surface 210 of the base plate 200 is a “flat surface” closest to the dielectric substrate 100 side in the base plate 200. In the present embodiment, a shape of the base plate 200 is a substantially cylindrical shape. Accordingly, the entire surface of the base plate 200 on the dielectric substrate 100 side is the surface 210 as a flat surface. In other words, an outer shape of the surface 210 (flat surface) in top view matches an outer shape of the base plate 200 in top view. A diameter of the surface 210 is, for example, 300 to 360 mm.

As described above, a part of the surface 210 is joined to the dielectric substrate 100 via the joining layer 300. A center of the surface 210 and the center of the surface 110 match with each other in top view. The outer shape of the surface 210 in top view is larger than the outer shape of the flange section 150 in top view. Accordingly, in top view, a part of the surface 210, which is not joined to the dielectric substrate 100, surrounds the flange section 150 along the entire periphery from an outside.

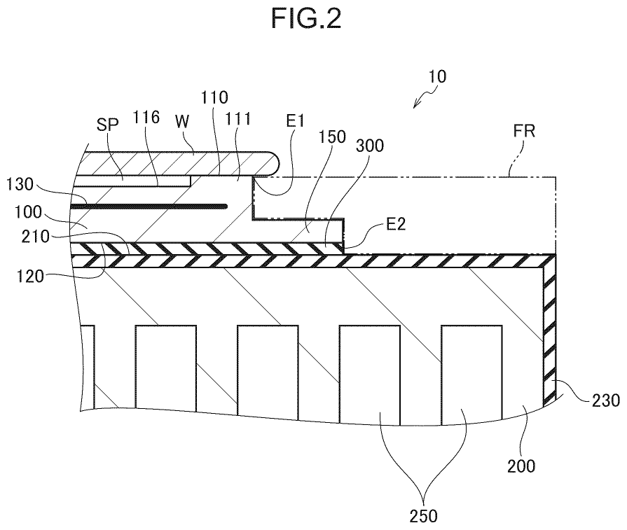

In the present embodiment, an insulating film 230 (not illustrated in FIG. 1; see FIG. 2) is formed on a surface of the base plate 200. As the insulating film 230, for example, an alumina film formed by thermal splaying can be used. When the surface of the base plate 200 is covered by the insulating film 230, it is possible to increase a withstand voltage of the base plate 200.

The insulating film 230 is preferably formed to entirely cover at least a surface facing the dielectric substrate 100 among surfaces of the base plate 200. In the present embodiment, the entire surface 210 serving as a “surface closest to the dielectric substrate 100 side in the base plate 200” is the surface of the insulating film 230. A thickness of the insulating film 230 is, for example, equal to or smaller than 1 mm. The thickness of the insulating film 230 may be uniform throughout but may vary depending on location. For example, a thickness of a part of the insulating film 230, which is in contact with the joining layer 300 may be smaller than the thickness of the surrounding insulating film 230.

In a case where occurrence of dielectric breakdown can be prevented by any other method, the insulating film 230 may not be formed on the base plate 200. In this case, the surface 210 serving as the “surface closest to the dielectric substrate 100 side in the base plate 200” is a surface at a metal part of the base plate 200.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings 255 and 256 (which are not illustrated in FIG. 1; see FIG. 2) formed on a surface 220 opposite to the surface 210 of the base plate 200. A specific configuration of the coolant flow path 250 will be described later.

When a process on the wafer W is to be performed in the semiconductor manufacturing apparatus, a focus ring which is not illustrated in FIG. 1 is installed on the part of the surface 210, which is not joined to the dielectric substrate 100. Dotted lines denoted by a reference sign “FR” in FIG. 2 illustrate a part where the focus ring is installed. The focus ring installed at such a position will also be hereinafter referred to as a “focus ring FR”. The focus ring FR is an annular and plate-like member made of an insulating material such as quartz, for example, and is installed for a purpose of regulating a distribution of plasma during the process. The dielectric substrate 100 is substantially entirely surrounded by the focus ring FR from an outer circumferential side.

In the present embodiment, the diameter of the surface 210 is relatively large, and the focus ring FR is substantially entirely supported by the surface 210 from below. The coolant flow path 250 is formed not only in a region immediately below the surface 110 serving as the placement surface but also in a region immediately below the focus ring FR. A part near an edge of the wafer W on the outer circumferential side is cooled through the dielectric substrate 100 as well as cooled through the focus ring FR. A heat transfer gel is preferably interposed between the surface 210 of the base plate 200 and the focus ring FR so that the focus ring FR is efficiently cooled by the base plate 200.

For convenience of description, an edge of the surface 110 serving as the placement surface on the outer circumferential side will also be hereinafter referred to as an “edge E1”. The edge E1 is a circular ridge in top view but may be a ridge different from a circular shape in some parts (for example, an orientation flat part).

A part exposed to the outside at an edge of the joining layer 300, which is closest to the outer circumferential side will also be hereinafter referred to as an “exposed part E2”.

While a process such as etching is performed on the wafer W, an edge of the joining layer 300 degrades through exposure to plasma and scatters, adversely affecting the wafer W being processed in some cases. For example, in a case where the dielectric substrate 100 is not provided with the flange section 150, the exposed part E2 of the joining layer 300 is exposed at a position immediately below the edge E1. Since a distance from the exposed part E2 to the edge E1 is relatively short, the influence on the wafer W as described above is potentially large.

Thus, in the electrostatic chuck 10 according to the present embodiment, the dielectric substrate 100 is provided with the flange section 150. Since the exposed part E2 is disposed at a position on the outer circumferential side of the position immediately below the edge E1, the distance from the exposed part E2 to the edge E1 is long and the influence on the wafer W as described above can be reduced.

It can be thought to extend the flange section 150 to a position overlapping an outer circumferential end of the surface 210 in top view such that the surface 210 is entirely covered by the dielectric substrate 100. However, with such a configuration, it is difficult to sufficiently ensure the strength of the flange section 150, and for example, damage on the flange section 150 along with thermal expansion potentially occurs.

As described above, the overall thickness of the dielectric substrate 100 is approximately 1 to 5 mm, and the thickness of the flange section 150 is approximately 0.5 to 4 mm. Recently, requirements for cooling performance and the like demanded of the electrostatic chuck 10 have increased, and thus it is expected that the dielectric substrate 100 and the flange section 150 will be further thinned in the future. Accordingly, in a case where the flange section 150 is largely extended to the outer circumferential side, the likelihood of damage on the flange section 150 as described above further increases. Furthermore, fabrication of the flange section 150 may become more difficult.

Thus, in the electrostatic chuck 10 according to the present embodiment, the flange section 150 is not extended up to a position for entirely covering the surface 210 (flat surface) of the base plate 200. Specifically, a protrusion amount of the flange section 150 toward the outer circumferential side is restrained to an extent that the surface 210 is exposed to surround a periphery of the flange section 150. With such a configuration, it is possible to ensure the strength of the flange section 150 as compared to a configuration in which the flange section 150 protrudes up to the position for entirely covering the surface 210.

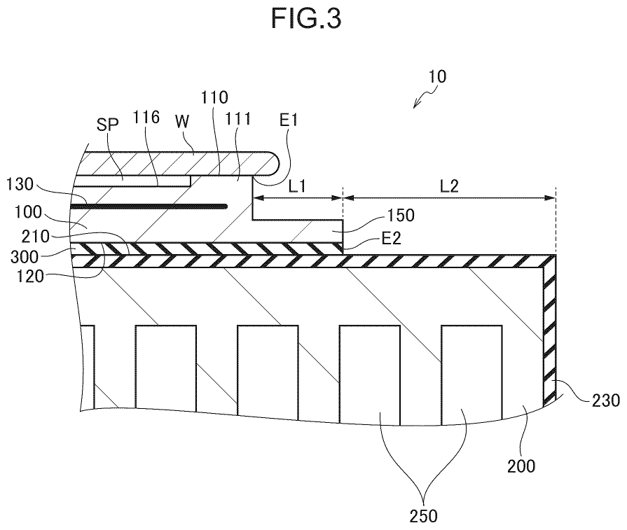

FIG. 3 is derived from FIG. 2 with the focus ring FR omitted, and instead, dimensions such as “L1” and “L2” added. In FIG. 3, “L1” represents a length of the flange section 150 along a radial direction, in other words, the protrusion amount of the flange section 150 toward the outer circumferential side. In the drawing, “L2” represents a length of the part of the surface 210 (flat surface), which is not joined to the dielectric substrate 100, along the radial direction.

In the present embodiment, the flange section 150 is provided such that the length (L1) of the flange section 150 along the radial direction is shorter than the length (L2) of the part of the surface 210, which is not joined to the dielectric substrate 100, along the radial direction. The length L1 is, for example, 1 to 10 mm. The length L2 is, for example, 20 to 30 mm.

The reason for this will be described below. As illustrated in FIG. 2, a part of the focus ring FR is disposed at a position immediately above the flange section 150 in the present embodiment. As described above, a heat transfer gel may be interposed between the surface 210 of the base plate 200 and the focus ring FR. However, it may be often difficult to interpose a heat transfer gel between the flange section 150 and the focus ring FR disposed immediately above. Since no gel is interposed, a heat resistance between the members may remain large, and accordingly, the part disposed immediately above the flange section 150 cannot be sufficiently cooled in some cases. As a result, a temperature of the focus ring FR may potentially locally increase.

Thus, in the present embodiment, the length of the flange section 150 along the radial direction may be kept to minimum necessary to achieve L1<L2 as described above. Accordingly, a region immediately above the flange section 150, in other words, a region difficult to sufficiently cool through the flange section 150 becomes smaller, which may make it possible to more reliably perform temperature adjustment of any member disposed immediately above the flange section 150.

The member disposed immediately above the flange section 150 may be a part of the focus ring FR as in the present embodiment but may be a member different from the focus ring FR. In any case, with the flange section 150 formed to satisfy the condition of L1<L2, it may be possible to more reliably perform temperature control of the flange section 150 and the member disposed immediately above.

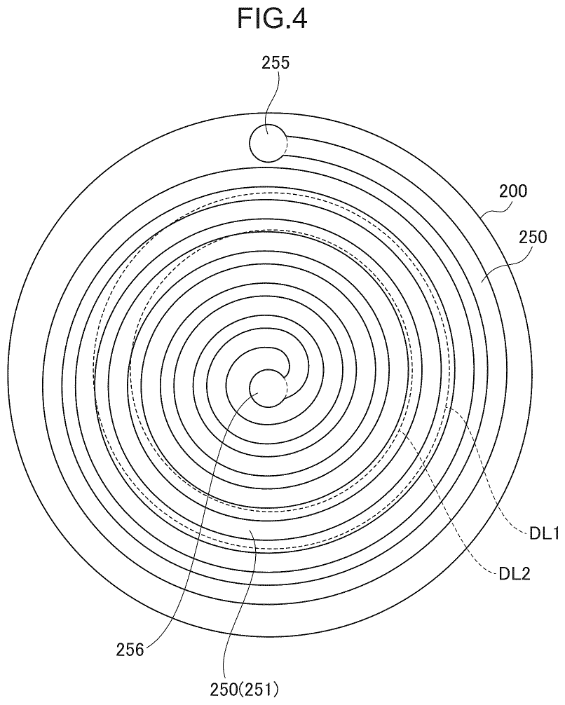

FIG. 4 schematically depicts the configuration of the coolant flow path 250 formed inside the base plate 200 in top view. As described above, the openings 255 and 256 are provided in the surface 220 of the base plate 200. The coolant flow path 250 is formed along such a route that connects the opening 255 and the opening 256. For example, the opening 255 is used as an inlet for the coolant, and the opening 256 is used as an outlet for the coolant.

A circular dotted line denoted by a reference sign “DL1” in FIG. 4 represents a position of an outer circumferential edge of the flange section 150. A circular dotted line denoted by a reference sign “DL2” represents a position of an inner circumferential edge of the flange section 150. A region between the dotted line DL1 and the dotted line DL2 is a region that overlaps the flange section 150 in top view. As illustrated in FIG. 4, a part (a part denoted by a reference sign “251”) of the coolant flow path 250 is formed to overlap the flange section 150 in top view and extend in an arc-like manner along the flange section 150.

With such a configuration, the flange section 150 can be efficiently cooled by the coolant flow path 250. Since the flange section 150 and any member immediately above are sufficiently cooled, their temperature increase can be reduced. Moreover, temperature increase of an outer circumferential side part of the wafer W can be reduced.

As described above, in the present embodiment, the shape of the base plate 200 is substantially cylindrical, the outer shape of the surface 210 (flat surface) in top view matches the outer shape of the base plate 200 in top view. However, the outer shapes of both members may be different from each other.

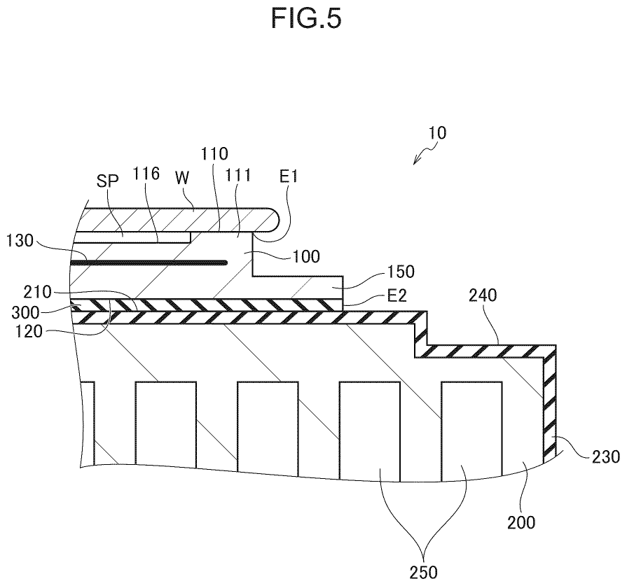

For example, as in a modification illustrated in FIG. 5, the outer shape of the surface 210 in top view may be smaller than the outer shape of the base plate 200 in top view. A part denoted by a reference sign “240” in the drawing is a part of the base plate 200 on the outer circumferential side of the surface 210 and is a recessed part formed to retract toward a side opposite to the dielectric substrate 100.

In this modification as well, the surface 210 corresponds to a “flat surface” which is closest to the dielectric substrate 100 side in the base plate 200. As in the present embodiment, the part of the surface 210 (flat surface), which is not joined to the dielectric substrate 100, surrounds the flange section 150 along the entire periphery from the outside in top view. With such a configuration as well, an effect similar to that described above in the present embodiment can be attained.

However, in the modification in FIG. 5, the focus ring FR (not illustrated) may have a large thickness immediately above a part denoted by a reference sign “240”. Thus, temperature adjustment of the focus ring FR may be potentially more difficult than in the present embodiment. In view of this point, the outer shape of the surface 210 (flat surface) in top view may match the outer shape of the base plate 200 in top view as in the present embodiment.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be attracted is placed; and
a base plate joined to the dielectric substrate, wherein
the dielectric substrate is provided with a flange section that is a part protruding outward along an entire periphery of a part of a side surface of the dielectric substrate on a base plate side,
the base plate includes a flat surface which is closest to a dielectric substrate side and a part of which is joined to the dielectric substrate, and
a part of the flat surface, which is not joined to the dielectric substrate, surrounds the flange section along the entire periphery when viewed from a direction perpendicular to the placement surface.

2. The electrostatic chuck according to claim 1, wherein an outer shape of the flat surface matches an outer shape of the base plate when viewed from the direction perpendicular to the placement surface.

3. The electrostatic chuck according to claim 1, wherein
a coolant flow path for allowing coolant to pass through is formed inside the base plate, and
a part of the coolant flow path is formed to overlap the flange section and extend along the flange section when viewed from the direction perpendicular to the placement surface.

4. The electrostatic chuck according to claim 1, wherein a length of the flange section along a radial direction is shorter than a length of the part of the flat surface, which is not joined to the dielectric substrate, along the radial direction.
